(19) United States
(12) Patent Application Publication
(10) Pub. No.: US 2026/0236645 A1
(43) Pub. Date: Aug. 13, 2026

(54) DIGITAL TWIN-BASED SEWAGE TREATMENT FACILITY OPERATION MANAGEMENT SYSTEM

(71) Applicant: GREENTECH INC., Gyeonggi-do (KR)

(72) Inventors: Chang-Woo Lee, Gyeonggi-do (KR); JeongYeob Woo, Gyeonggi-do (KR); Ji Yong Lee, Gyeonggi-do (KR); Ki Yeon Lee, Gyeonggi-do (KR); Kyu Hyoung Choi, Gyeonggi-do (KR)

(73) Assignee: GREENTECH INC., Gyeonggi-do (KR)

(21) Appl. No.: 19/376,916

(22) Filed: Nov. 1, 2025

(30) Foreign Application Priority Data
Nov. 1, 2024 (KR) 10-2024-0153703

(51) Int. Cl. G06F 30/27; C02F 3/00; C02F 3/02; C02F 3/28; C02F 103/00; G06Q 50/06

(52) U.S. Cl. CPC G06F 30/27; C02F 3/006; C02F 3/02; C02F 3/28; G06Q 50/06; C02F 2103/005; C02F 2203/006; C02F 2209/10; C02F 2209/44

(57) ABSTRACT

A digital twin-based sewage treatment facility operation management system according to an exemplary embodiment of the present disclosure includes a data collection/storage unit which collects and stores data including a sewage treatment process operation parameter and an operation status of a sewage treatment facility in real time; a water quality prediction unit which predicts an effluent water quality according to a sewage treatment process of the sewage treatment facility using a sewage treatment process operation parameter of the sewage treatment facility, based on an algorithm of an artificial intelligence model; an anomaly detection unit which detects anomaly of each sewage treatment process of the sewage treatment facility when the effluent water quality predicted by the water quality prediction unit exceeds a predetermined water quality level, based on an algorithm of an artificial intelligence model; an optimal parameter deduction unit which deduces an operation parameter of the sewage treatment process generated when an operation status of the sewage treatment facility is controlled, during the detection of the anomaly of the sewage treatment process by the anomaly detection unit, based on an algorithm of an artificial intelligence model; and a digital twin system unit which constructs a digital twin 3D model which reproduces the sewage treatment facility as a virtual 3D graphic by applying a 3D asset of the sewage treatment facility, structuralizes the 3D asset to have attributes of a driving unit which is a set of dynamic information to reflect a physical behavior of the sewage treatment facility in the digital twin 3D model to a virtual space of the digital twin 3D model and an information unit which is a set of static information and includes an linkage unit which serves as an interface to collect data and provide information together with the driving unit and the information unit.

### GOVERNMENT LICENSE STATEMENT

This invention was made with the support of the National Research and Development Project of the Republic of Korea (Project Unique Number: Not Assigned; Project Number: B0080429002368), funded by the Ministry of Environment and managed by the Korea Environmental Industry & Technology Institute. The research was conducted under the program “Support Project for Commercialization of Small and Medium-Sized Environmental Companies,” specifically the project entitled “Commercialization of a Digital Twin-Based Sewage Treatment Facility Operation Management System Integrated with Artificial Intelligence,” performed by GREENTECH INC. during the period from Apr. 1, 2024 to Nov. 1, 2024.

### CROSS-REFERENCE TO RELATED APPLICATIONS

This application claims the priority of Korean Patent Application No. 10-2024-0153703 filed on Nov. 1, 2024, in the Korean Intellectual Property Office, the disclosure of which is incorporated herein by reference.

### BACKGROUND

### Field

The present disclosure relates to a digital twin-based sewage treatment facility operation management system, and more particularly, to a digital twin-based sewage treatment facility operation management system which performs real-time monitoring, artificial intelligence water quality prediction, process diagnosis, and management of a sewage treatment facility based on a digital twin model.

[National R&D projects supporting the present invention]

[Project ID] Not assigned

[Project No.] B0080429002368

[Ministry in charge] Ministry of the Environment

[Research management (specialist) agency] Korea Environmental Industry & Technology Institute

[Research project name] Commercialization support project for small and medium environmental companies

[Research title] Commercialization of integrated sewage treatment facility operation system based on artificial intelligence and digital twin convergence technology

[Research institution name] GREENTECH INC.

[Research period] Apr. 1, 2024 to Dec. 31, 2024

### DESCRIPTION OF THE RELATED ART

Among public infrastructures, specifically, in a sewage treatment plant, the facility has a lot of components so that it is not easy to confirm the serious deterioration until an accident occurs. Further, socioenvironmental costs required to recover after the accident of the deteriorated sewage treatment facility are significantly larger than ordinary maintenance expenses or development and repair costs.

Accordingly, as a maintenance strategy for sewage treatment plants, it is necessary to depart from the conventional concept of post-incident maintenance and introduce a technique of preventive maintenance concept.

### RELATED ART DOCUMENT

### Patent Document

(Patent Document 1) Korean Registered Patent No. 10-1597230 (registered on Feb. 18, 2016)

### SUMMARY

Accordingly, the present disclosure has been devised to solve the problems as described above and an object of the present disclosure is to provide a digital twin-based sewage treatment facility operation management system which performs real-time monitoring of a sewage treatment facility, artificial intelligence water quality prediction, process diagnosis, and management based on a digital twin model for preventive maintenance of the sewage treatment facility.

Further, an object of the present disclosure is to provide a digital twin-based sewage treatment facility operation management system including a digital twin system unit configured by a driving unit which is a set of dynamic information to construct a digital twin 3D model by applying a 3D asset of a sewage treatment facility and allow the 3D asset to reflect a physical behavior of the sewage treatment facility to a virtual space of the digital twin 3D model and an linkage unit which structuralizes the 3D asset to have an attribute of an information unit which is a set of static information and serves as an interface to collect data and provide information together with the driving unit and the information unit.

Technical objects to be achieved in the present disclosure are not limited to the aforementioned technical objects, and other not-mentioned technical objects will be clearly understood by those skilled in the art from the description below.

In order to achieve the above-described objects, according to an aspect of the present disclosure, a digital twin-based sewage treatment facility operation management system includes a data collection/storage unit which collects and stores data including a sewage treatment process operation parameter and an operation status of a sewage treatment facility in real time; a water quality prediction unit which predicts an effluent water quality according to a sewage treatment process of the sewage treatment facility using a sewage treatment process operation parameter of the sewage treatment facility, based on an algorithm of an artificial intelligence model; an anomaly detection unit which detects anomaly of each sewage treatment process of the sewage treatment facility when the effluent water quality predicted by the water quality prediction unit exceeds a predetermined water quality level, based on an algorithm of an artificial intelligence model; an optimal parameter deduction unit which deduces an operation parameter of the sewage treatment process generated when an operation status of the sewage treatment facility is controlled, during the detection of the anomaly of the sewage treatment process by the anomaly detection unit, based on an algorithm of an artificial intelligence model; and a digital twin system unit which constructs a digital twin 3D model which reproduces the sewage treatment facility as a virtual 3D graphic by applying a 3D asset of the sewage treatment facility, structuralizes the 3D asset to have attributes of a driving unit which is a set of dynamic information to reflect a physical behavior of the sewage treatment facility in the digital twin 3D model to a virtual space of the digital twin 3D model and an information unit which is a set of static information and includes an linkage unit which serves as an interface to collect data and provide information together with the driving unit and the information unit.

according to an exemplary embodiment of the present disclosure may further include a comprehensive analysis unit which proceeds a simulation of a scenario assuming that the operation parameter of the sewage treatment process to the sewage treatment process and deduces a water quality prediction result obtained by predicting a water quality of the sewage treatment process based on the simulation.

The operation parameter of the sewage treatment process is at least one setting value, among power consumption, a chemical dosing amount, a ventilation rate, a recycled sludge amount, hydraulic retention time (HRT), solid retention time (SRT), mixed liquor suspended solids (MLSS), and an internal recycle rate, which allows a water quality of an effluent water to comply with the predetermined water quality level.

Further, the digital twin system unit may display the water quality prediction result in the virtual space of the digital twin 3D model.

according to an exemplary embodiment of the present disclosure may further include a monitoring unit which monitors a sewage treatment process operation parameter and an operation status of the sewage treatment facility which are stored in the data collection/storage unit in real time.

Further, the operation status of the sewage treatment facility may include an operation status of a process facility which is a subsystem of a structure which configures the sewage treatment facility and equipment which is a subsystem of the process facility.

Further, the operation status of the sewage treatment facility may include an operation status of a process facility which is a subsystem of a structure which configures the sewage treatment facility and equipment which is a subsystem of the process facility.

The digital twin system unit may display the sewage treatment process operation parameter and the operation status of the sewage treatment facility in a virtual space of the digital twin 3D model.

Further, the digital twin-based sewage treatment facility operation management system according to an exemplary embodiment of the present disclosure may further include a structure information unit which transmits structure information to the digital twin system unit to allow the structure information to be displayed in a virtual space of the digital twin 3D model.

The structure information may be data including specifications, drawings, and photographs of a structure which configures the sewage treatment facility, a process facility which is a subsystem of the structure, equipment and auxiliary equipment which are subsystems of the process facility, maintenance histories and CCTV monitoring screens of the structure, the process facility, the equipment, and the auxiliary equipment.

Further, the digital twin system unit may display the structure information in the virtual space of the digital twin 3D model.

After applying 3D assets of the structure, the process facility, the equipment, and the auxiliary equipment which are the sewage treatment facility 10 to extract 3D asset models of the structure, the process facility, the equipment, and the auxiliary equipment, respectively, the digital twin system unit configures an asset hierarchy in which the structure 3D asset model serves as a supersystem of the process facility 3D asset model and the process facility 3D asset model serves as a supersystem of the equipment 3D asset model and the auxiliary equipment 3D asset model to organize the relationship between the 3D asset models, and may display the 3D asset models of the structure, the process facility, the equipment, and the auxiliary equipment in the virtual space of the digital twin 3D model based on the configuration of the asset hierarchy.

Further, the process facility may be a reaction tank including a primary precipitate tank, an anaerobic tank, an anoxic tank, an aerobic tank, or a biofilm, and a sequencing batch reactor.

The equipment may be a pump, a valve, and a motor which operate to proceed the sewage treatment process.

Further, the auxiliary equipment may be a foothold and a fence installed in the structure.

The digital twin system unit may present the digital twin 3D model to a user in the form of a user interface.

According to the present disclosure, the digital twin 3D model is constructed to enable real-time monitoring of a sewage treatment facility, artificial intelligence water quality prediction, process diagnosis, and management, thereby achieving preventive maintenance of the sewage treatment facility.

Further, according to the present disclosure, a digital twin 3D model in which a 3D asset is structuralized with a driving unit for reflecting a physical behavior of the sewage treatment facility to a virtual space of the digital twin 3D model and an information unit configured by information about the driving unit may be provided.

Effects to be achieved by the present disclosure are not limited to the aforementioned effects, and other effects which have not been mentioned will be obviously understood by those skilled in the art from the description below.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram schematically illustrating components of a digital twin-based sewage treatment facility operation management system according to an exemplary embodiment of the present disclosure;

FIG. 2 is a flowchart illustrating a process of an AI solution for training, evaluating, and verifying artificial intelligence models configured in a water quality prediction unit, an anomaly detection unit, and an optimal parameter deduction unit according to an exemplary embodiment of the present disclosure;

FIG. 3 is a view for explaining a 3D asset structuralization of a sewage treatment facility according to an exemplary embodiment of the present disclosure;

FIG. 4 is a block diagram illustrating an example of a process facility according to an exemplary embodiment of the present disclosure;

FIG. 5 is a block diagram illustrating an example of a 3D asset model of a sewage treatment facility according to an exemplary embodiment of the present disclosure;

FIG. 6 is a view illustrating an example of a 3D asset model of a valve which is equipment according to an exemplary embodiment of the present disclosure;

FIG. 7 is a view illustrating an example of a 3D asset model of a motor which is equipment according to an exemplary embodiment of the present disclosure;

FIG. 8 is a view for explaining a providing method of a digital twin 3D model according to an exemplary embodiment of the present disclosure; and

FIG. 9 is a view schematically illustrating a configuration of a digital twin system unit according to an exemplary embodiment of the present disclosure.

### DETAILED DESCRIPTION OF THE EMBODIMENT

Hereinafter, exemplary embodiments of the present disclosure will be described more fully with reference to the accompanying drawings for those skilled in the art to easily implement the present disclosure. Description of the present disclosure is just an embodiment for structural and functional description so that the scope of the present disclosure is not interpreted to be limited by the embodiment described in the specification. That is, the embodiment may be modified in various forms so that it is understood that the scope of the present disclosure has equivalents which are capable of implementing the technical spirit. Further, it does not mean that the specific embodiment includes the object or effect proposed in the present disclosure or includes only the effect so that it is not understood that the scope of the present disclosure is limited thereby.

In the meantime, meanings of terms described in the present disclosure can be understood as follows.

The terms “first” or “second” are used to distinguish one component from the other component so that the scope should not be limited by these terms. For example, a first component may be referred to as a second component, and similarly, a second component may be referred to as a first component. It should be understood that, when it is described that an element is “connected” to another element, the element may be directly connected to the other element or connected to the other element through a third element. In contrast, it should be understood that, when it is described that an element is “directly connected” to another element, no element is present between the element and the other element. Other expressions which describe the relationship between components, that is, “between” and “directly between”, or “adjacent to” and “directly adjacent to” need to be interpreted by the same manner.

Unless the context apparently indicates otherwise, it should be understood that terms “include” or “have” indicate that a feature, a number, a step, an operation, a component, a part or the combination thereof described in the specification is present, but do not exclude a possibility of presence or addition of one or more other features, numbers, steps, operations, components, parts or combinations thereof, in advance.

Unless they are contrarily defined, all terms used herein including technological or scientific terms have the same meaning as those generally understood by a person with ordinary skill in the art. Terms which are defined in a generally used dictionary should be interpreted to have the same meaning as the meaning in the context of the related art, but are not interpreted as an ideally or excessively formal meaning if it is not clearly defined in the present disclosure.

### Sewage Treatment Facility Operation Management System

Hereinafter, a configuration of an exemplary embodiment of a digital twin-based sewage treatment facility operation management system 100 of the present disclosure will be described in detail with reference to the accompanying drawings.

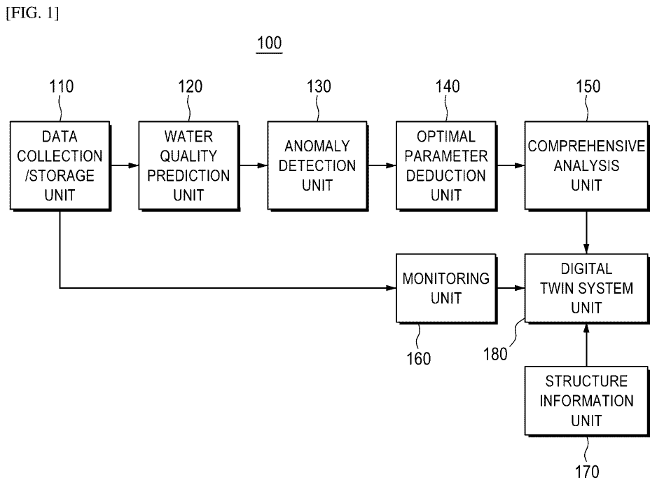

The digital twin-based sewage treatment facility operation management system 100 is a system which performs real-time monitoring of a sewage treatment facility, artificial intelligence water quality prediction and process diagnosis, and management based on a digital twin model and may include components illustrated in FIG. 1 to achieve this purpose.

FIG. 1 is a block diagram schematically illustrating components of a digital twin-based sewage treatment facility operation management system according to an exemplary embodiment of the present disclosure.

Referring to FIG. 1, the sewage treatment facility operation management system 100 of the present disclosure may include a data collection/storage unit 110, a water quality prediction unit 120, an anomaly detection unit 130, an optimal parameter deduction unit 140, a comprehensive analysis unit 150, a monitoring unit 160, a structure information unit 170, and a digital twin system unit 180.

In one exemplary embodiment, the data collection/storage unit 110 may collect and store data including a sewage treatment process operation parameter and an operation status of the sewage treatment facility 10 in real time.

At this time, the data collection/storage unit 110 may collect and store data including a sewage treatment process operation parameter and an operation status of the sewage treatment facility 10 in association with HMI or SCADA system of the sewage treatment facility 10.

Further, even though the sewage treatment process operation parameter of the sewage treatment facility 10 is not limited, in the exemplary embodiment, it may refer to an operation parameter for each reaction tank which is a process facility 12 which is a subsystem of the structure 11 which configures the sewage treatment facility 10.

Here, the operation parameter for each reaction tank may include a flow rate of sewage flowing into the sewage treatment facility 10 and information values of sewage regarding a raw water quality, such as a pH, a temperature, or dissolved oxygen (DO).

In addition, the operation parameter for each reaction tank may be at least one of setting values of the reaction tank, such as setting values of power consumption of a reaction tank, a chemical dosing amount, a ventilation rate, a recycled sludge amount, hydraulic retention time (HRT), solid retention time (SRT), mixed liquor suspended solids (MLSS), and an internal recycle rate.

That is, the operation parameter for the reaction tank stored in the data collection/storage unit 110 may include information values of the sewage and setting values of the reaction tank.

Even though the operation status of the sewage treatment facility 10 is not limited, in the exemplary embodiment, the operation status may include operation statuses of the process facility 12 which is a subsystem of the structure 11 which configures the sewage treatment facility 10 and equipment 13 which is a subsystem of the process facility 12.

In one exemplary embodiment, the water quality prediction unit 120 may predict an effluent water quality according to the sewage treatment process of the sewage treatment facility 10 using the sewage treatment process operation parameter of the sewage treatment facility 10 based on an algorithm of the artificial intelligence model.

At this time, even though a type of the artificial intelligence model of the water quality prediction unit 120 is not limited, in one exemplary embodiment, the artificial intelligence model may be a regression model to predict an effluent water quality.

Further, even though a type of the algorithm of the regression model configured in the water quality prediction unit 120 is not limited, in the exemplary embodiment of the present disclosure, the algorithm of the regression model may be a regression algorithm and the regression algorithm used for the regression model of the water quality prediction unit 120 to predict the effluent water quality may be at least one of XGBoost, Light GBM, CatBoost, and Auto Arima.

XGBoost, Light GBM, CatBoost, and Auto Arima which are the regression algorithms described above in the present disclosure are generally known algorithms so that a detailed description thereof will be omitted for the sake of the convenience.

In one exemplary embodiment, the water quality prediction unit 120 may predict an effluent water quality according to the sewage treatment process of the sewage treatment facility 10, based on external conditions at a time when the sewage flows into the sewage treatment facility 10.

Here, the external conditions may include season, rainfall amount, day of the week (weekday/weekend), external temperature, and occurrence of algal bloom at the time when the sewage flows into the sewage treatment facility 10.

That is, the water quality prediction unit 120 may predict an effluent water quality according to the sewage treatment process of the sewage treatment facility 10 using the sewage treatment process operation parameter of the sewage treatment facility 10 and the external conditions, based on an algorithm of the regression model.

Further, even though it is not illustrated in the drawing, the sewage treatment facility operation management system 100 desirably includes a measurement unit (not illustrated), such as a sensor, which measures the external conditions and transmits the external conditions to the water quality prediction unit 120 to allow the water quality prediction unit 120 to predict the effluent water quality based on the external conditions.

In the exemplary embodiment, when the effluent water quality predicted by the water quality prediction unit 120 exceeds a predetermined water quality criterion, the anomaly detection unit 130 may detect an anomaly for each sewage treatment process of the sewage treatment facility 10 based on the algorithm of the artificial intelligence model.

Here, the effluent water quality may be determined based on data, such as BOD, TOC, SS, T-N, T-P, and coliform count.

Further, the predetermined water quality refers to a water quality of the sewage which flows into the sewage treatment facility 10, to undergo the treatment process to be converted into an effluent water and then discharged to an effluent water body from the sewage treatment facility 10.

The anomaly detection unit 130 desirably detects the anomaly when the effluent water quality predicted based on data, such as BOD, TOC, SS, T-N, T-P, and coliform count exceeds a predetermined water quality.

Further, even though a type of the artificial intelligence model of the anomaly detection unit 130 is not limited, in one exemplary embodiment, the artificial intelligence model may be a first deep learning model which detects the anomaly for each sewage treatment process of the sewage treatment facility 10.

The sewage treatment process which allows the first deep learning model configured in the anomaly detection unit 130 to detect the anomaly refers to a treatment process of the reaction tank which is a process facility 12 which configures the sewage treatment facility 10.

Even though a type of the algorithm of the first deep learning model configured in the anomaly detection unit 130 is not limited, in the exemplary embodiment, the algorithm of the first deep learning model may be a deep learning algorithm. Further, a deep learning algorithm which is used by the first deep learning model of the anomaly detection unit 130 to detect the anomaly of each sewage treatment process of the sewage treatment facility 10 may be at least one of ECOD, COPOD, and Autoencoder.

ECOD, COPOD, and Autoencoder which are the deep learning algorithms described above in the present disclosure are generally known algorithms so that a detailed description thereof will be omitted for the sake of the convenience.

When the effluent water quality predicted by the water quality prediction unit 120 exceeds a predetermined water quality criterion, the anomaly detection unit 130 may detect an anomaly of the effluent water flowing into the sewage treatment facility 10 based on the external condition at a time when the sewage flows into the sewage treatment facility 10.

That is, when the effluent water quality predicted by the water quality prediction unit 120 exceeds a predetermined water quality criterion, the anomaly detection unit 130 may detect an anomaly for each sewage treatment process of the sewage treatment facility 10 using the external conditions based on the algorithm of the first deep learning model.

Further, in order to detect the anomaly of the sewage flowing into the sewage treatment facility 10, the anomaly detection unit 130 desirably receives the external conditions from the measurement unit of the sewage treatment facility operation management system 100.

In one exemplary embodiment, when the anomaly detection unit 130 detects the anomaly of the sewage treatment process, the optimal parameter deduction unit 140 may deduce the operation parameter of the sewage treatment process which is generated when the operation status of the sewage treatment facility 10 is controlled, based on the algorithm of the artificial intelligence model.

At this time, even though a type of the artificial intelligence model of the optimal parameter deduction unit 140 is not limited, in the exemplary embodiment, the artificial intelligence model may be a second deep learning model which deduces the operation parameter of the sewage treatment process.

Further, even though the operation parameter of the sewage treatment process is not limited, in one exemplary embodiment, the operation parameter may be at least one setting value, among power consumption of the reaction tank, a chemical dosing amount, a ventilation rate, a recycled sludge amount, hydraulic retention time (HRT), solid retention time (SRT), mixed liquor suspended solids (MLSS), and an internal recycle rate, which changes an effluent water quality discharged from the sewage treatment facility 10 to a predetermined dischargeable water quality level or higher.

Even though a type of the algorithm of the second deep learning model configured in the optimal parameter deduction unit 140 is not limited, in the exemplary embodiment, the algorithm of the second deep learning model may be a deep learning algorithm. Further, a deep learning algorithm which is used by the second deep learning model of the optimal parameter deduction unit 140 to deduce the operation parameter of the sewage treatment process may be at least one of ECOD, COPOD, and Autoencoder, which is the same as the anomaly detection unit 130.

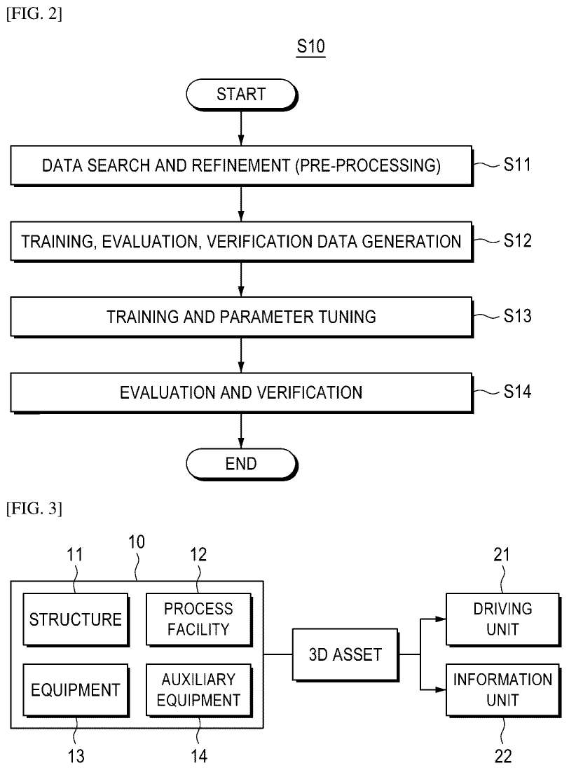

In the meantime, the water quality prediction unit 120, the anomaly detection unit 130, and the optimal parameter deduction unit 140 of the present disclosure need to allow each artificial intelligence model to undergo an AI solution S10 of FIG. 2 to be trained, evaluated, and verified, to operate in accordance with each purpose based on the algorithm of the artificial intelligence model to predict the water quality, detect the anomaly, and deduce the operation parameter of the treatment process.

FIG. 2 is a flowchart illustrating a process of an AI solution for training, evaluating, and verifying artificial intelligence models configured in a water quality prediction unit, an anomaly detection unit, and an optimal parameter deduction unit according to an exemplary embodiment of the present disclosure.

Referring to FIG. 2, the AI solution S10 of the present disclosure may perform a data search and refinement step S11, a training, evaluation, and verification data generation step S12, a training and parameter tuning step S13, and an evaluation and verification step S14 in this order.

In order to proceed with the data search and refinement step S11, the sewage treatment facility operation management system 100 of the present disclosure may further include a data search unit, a data refinement unit, and a parameter tuning unit which are not illustrated in the drawing.

In the data search and refinement step S11, the data search unit (not illustrated) may receive data stored in the data collection/storage unit 110 to train, evaluate, and verify the artificial intelligence model from the data collection/storage unit 110 and search a noise, such as outliers and missing values which are not necessary for the training of the artificial intelligence model, from the received data.

In the data search and refinement step S11, the data refinement unit (not illustrated) may refine (pre-process) data by removing the searched noise from the data so as to allow the data from which the noise is searched to be used to train the artificial intelligence model.

In the training, evaluation, and verification data generation step S12, if the data refinement unit (not illustrated) removes the noise from the data, the data may be generated as data to be used to train, evaluate, and verify the artificial intelligence models of the water prediction unit 120, the anomaly detection unit 130, and the optimal parameter deduction unit 140.

In the training and parameter tuning step S13, the parameter tuning unit (not illustrated) selects an optimal parameter of the regression model and the first and second deep learning models which are artificial intelligence models and applies a Boosting method to progressively train the regression model and the first and second deep learning models.

In the training and parameter tuning step S13, the parameter tuning unit may improve the performances of the regression model and the first and second deep learning models based on diversified tuning methods, such as GridsearchCV, OPtuna, and Flaml.

Here, GridsearchCV, OPtuna, and Flaml which are tuning methods are generally known tuning methods so that the detailed description thereof will be omitted for the sake of convenience.

In the evaluation and verification step S14, the regression model and the first and second deep learning models may be evaluated and verified to determine whether the regression model and the first and second deep learning models operate to enable water quality prediction and anomaly detection based on data refined by the data refinement unit (not illustrated) after performance improvement. After this process, the regression model and the first and second deep learning models are configured (or mounted) in the water quality prediction unit 120, the anomaly detection unit 130, and the optimal parameter deduction unit 140 to predict the water quality, detect the anomaly, and deduce operation parameters of the sewage treatment process.

Referring to FIG. 1 again, the comprehensive analysis unit 150 may perform a simulation of a scenario assuming that the operation parameter of the sewage treatment process is applied to the sewage treatment process from which the anomaly has been detected.

Further, the comprehensive analysis unit 150 may deduce a water quality prediction result obtained by predicting a water quality of the sewage treatment process based on the simulation and transmit the water quality prediction result deduced based on the simulation to the digital twin system unit 180.

After performing the simulation, the comprehensive analysis unit 150 may propose an optimal operation plan of the process facility 12 to treat the effluent water quality to be equal to or lower than a predetermined water quality according to the result of the simulation and transmit the optimal operation plan to the digital twin system unit 180.

In one exemplary embodiment, the monitoring unit 160 may monitor the sewage treatment process operation parameter and the operation status of the sewage treatment facility 10 which are stored in the data collection/storage unit 110 in real time and transmit the monitored sewage treatment process operation parameter and operation status to the digital twin system unit 180.

In one exemplary embodiment, the structure information unit 170 may transmit the structure information to the digital twin system unit 180.

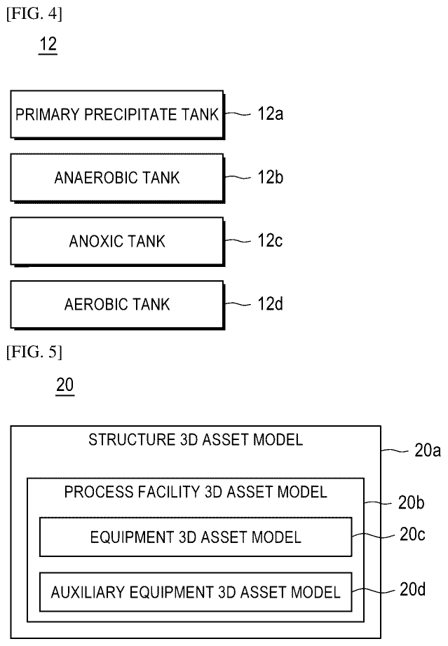

At this time, as illustrated in FIG. 3, the structure information may include data including specifications, drawings, and photographs of a structure 11 which configures the sewage treatment facility 10, a process facility 12 which is a subsystem of the structure 11, equipment 13 and auxiliary equipment 14 which are subsystems of the process facility 12, maintenance histories and CCTV monitoring screens of the structure 11, the process facility 12, the equipment 13, and the auxiliary equipment 14.

In one exemplary embodiment, the digital twin system unit 180 may construct a digital twin model which performs real-time monitoring of the sewage treatment facility 10, artificial intelligence water quality prediction, and process diagnosis and management.

At this time, the digital twin model which is constructed by the digital twin system unit 180 may refer to a digital twin 3D model which applies a 3D asset to reproduce the sewage treatment facility 10 as a virtual 3D graphic and the 3D asset of the sewage treatment facility 10 may be structuralized as illustrated in FIG. 3.

FIG. 3 is a view for explaining a 3D asset structuralization of a sewage treatment facility according to an exemplary embodiment of the present disclosure.

Referring to FIG. 3, in the present disclosure, the sewage treatment facility 10 may include a structure 11, a process facility 12 which is a subsystem of the structure 11, equipment 13 and auxiliary equipment 14 which are subsystems of the process facility 12.

In one exemplary embodiment, the structure 11 is a building of the sewage treatment facility 10 including an administration building or a chemical building.

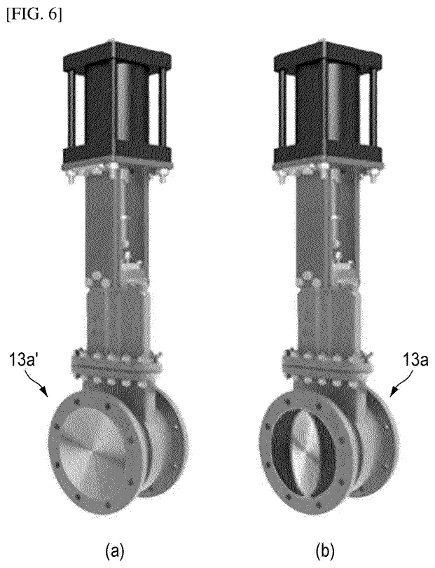

In one exemplary embodiment, the treatment facility 12 refers to a reaction tank which treats the sewage flowing into the sewage treatment facility 10 as an effluent water having a predetermined water quality or higher and the reaction tank of the sewage treatment facility 10 may be configured as illustrated in FIG. 4.

FIG. 4 is a block diagram illustrating an example of a process facility according to an exemplary embodiment of the present disclosure.

Referring to FIG. 4, the process facility 12 may include a primary precipitate tank 12a, an anaerobic tank 12b, an anoxic tank 12c, and an aerobic tank 12d.

At this time, the primary precipitate tank 12a precipitates large and heavy solids (for example, soil, sand, and residues) included in the sewage flowing into the sewage treatment facility 10 by gravity, thereby reducing total suspended solids (TSS) of the sewage and a part of organic materials (TOC, BOD).

Further, the anaerobic tank 12b may decompose organic materials of the sewage which passes through the primary precipitate tank and remove biological phosphorus (P) using microorganisms under the anaerobic conditions in which the microorganisms which do not require oxygen can be active.

The anoxic tank 12c may perform a denitrification process which converts nitrates (NO₃⁻) of the sewage which passes through the anaerobic tank 12c into nitrogen gas (N₂) under the anoxic condition using denitrifying microorganisms, discharge the nitrogen gas generated during the denitrification process to the atmosphere. Therefore, a nitrogen concentration in the sewage may be reduced.

Further, the aerobic tank 12d may oxidize (decompose) organic materials in the sewage which pass through the anoxic tank 12c, using the microorganisms under the aerobic conditions in which oxygen is supplied, and perform the nitrification process which converts ammoniac nitrogen (NH₄ ⁺) into nitrates (NO₃⁻), thereby removing pollutants from the sewage.

The sewage flowing into the sewage treatment facility 10 may be treated step by step while passing the primary precipitate tank 12a, the anaerobic tank 12b, the anoxic tank 12c, and the aerobic tank 12d in this order and then be discharged as an effluent water. Further, the process facility may be configured by other facilities, such as a biofilm or a sequencing batch reactor.

Referring to FIG. 3 again, the facility 13 refers to a pump, a valve 13a, and a motor 13b of the process facility 12 which can be active (or operable).

Unlike the operable equipment 13, the auxiliary equipment 14 refers to a foothold or fence of the process facility 12, rather than a configuration which is active (or operates).

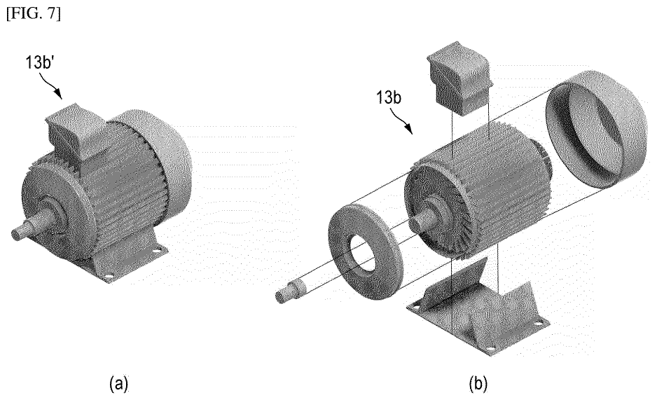

FIG. 5 is a block diagram illustrating an example of a 3D asset model of a sewage treatment facility according to an exemplary embodiment of the present disclosure.

Referring to FIG. 5, the digital twin system unit 180 applies 3D assets of the structure 11, the process facility 12, the equipment 13, and the auxiliary equipment 14 which are the sewage treatment facility 10 to extract a structure 3D asset model 20a, a process facility 3D asset model 20b, an equipment 3D asset model 20c, and an auxiliary equipment 3D asset model 20d.

Further, the digital twin system unit 180 configures an asset hierarchy in which the structure 3D asset model 20a serves as a supersystem of the process facility 3D asset model 20b and the process facility 3D asset model 20b serves as a supersystem of the equipment 3D asset model 20c and the auxiliary equipment 3D asset model 20d to organize the relationship between the 3D asset models.

The digital twin system unit 180 may display the 3D asset models 20a to 20d in a virtual space of the digital twin 3D model based on the configuration of the asset hierarchy.

Further, the digital twin system unit 180 may display the water quality prediction result and the optimal operation plan received from the comprehensive analysis unit 150, the sewage treatment process operation parameter and the operation status of the sewage treatment facility 10 received from the monitoring unit 160, and the structure information received from the structure information unit 170 in the virtual space of the digital twin 3D model.

Further, the digital twin system unit 180 may structuralize the 3D asset 20 for constructing a digital twin 3D model to have attributes of a driving unit 21 which is a set of dynamic information and an information unit 22 which is a set of static information.

At this time, the driving unit 21 may reflect the physical behavior of the sewage treatment facility 10 in the digital twin 3D model to the virtual space of the digital twin 3D model and the digital twin 3D model may display the physical behavior of the sewage treatment facility 10 in the virtual space by means of the driving unit 21.

The driving unit 21 may be a set of a physical behavior or motion, or movement to express the dynamic movements of the 3D asset 20 (for example, a minimum number of revolutions, a maximum number of revolutions, an operational range of 0 to 180°) in the virtual space.

Further, the information unit 22 may reflect static items of the sewage treatment facility 10 of the 3D asset (for example, a width, a breadth, and a weight) to the virtual space of the digital twin 3D model and the digital twin 3D model may implement the sewage treatment facility 10 in the virtual space by means of the information unit 22.

In the meantime, all the 3D assets 20 of the present disclosure have the attribute of the information unit 22 regardless of whether the physical behavior occurs and an asset model which requires the operation, such as a valve or a motor may further include an attribute of the driving unit 21.

In one exemplary embodiment, the 3D asset 20 which displays the physical behavior of the sewage treatment facility 10 in the virtual space of the digital twin 3D model may be the process facility 3D asset model 20b or the equipment 3D asset model 20c in which the physical behavior occurs.

Hereinafter, the physical behavior of the sewage treatment facility 10 will be described in detail with respect to the equipment 3D asset model 20c.

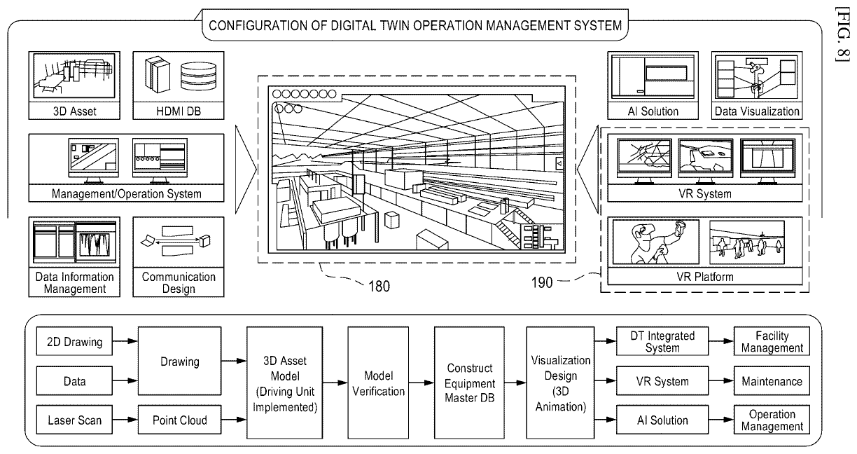

FIG. 6 is a view illustrating an example of a 3D asset model of a valve which is equipment according to an exemplary embodiment of the present disclosure.

Referring to FIG. 6A, in the related art, only aperture rate information of a valve 13a′ may be displayed in the virtual space of the digital twin model as a text in percentage (%) units using the 3D asset model of the valve 13a′.

Referring to FIG. 6B, unlike the related art, the 3D asset model 20c of the valve 13a corresponding to the equipment 13 displays the open state of the valve 13a in the virtual space of the digital twin 3D model together with the valve 13a.

Further, unlike the related art, the 3D asset model 20c of the valve 13a displays not only the aperture rate information of the valve 13a, but also the change in a recycled sludge amount according to the aperture rate of the valve 13 a in the virtual space of the digital twin 3D model with an animation effect.

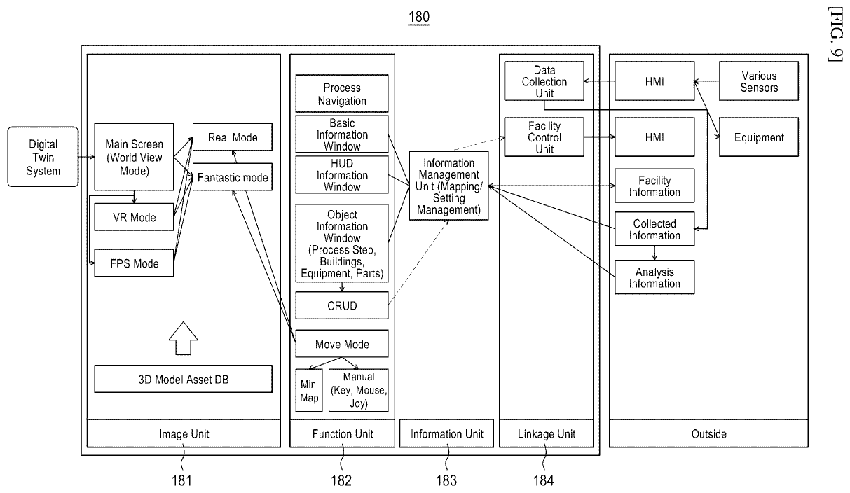

FIG. 7 is a view illustrating an example of a 3D asset model of a motor which is equipment according to an exemplary embodiment of the present disclosure

Referring to FIG. 7A, in the related art, a 3D asset model of a motor 13b′ applies the 3D asset in which a rotator in which the physical behavior occurs is enclosed by the frame so that the physical behavior is not displayed in the virtual space of the digital twin model.

Referring to FIG. 7B, unlike the related art, the 3D asset model 20c of the motor 13b which corresponds to the equipment 13 divides a component in which the physical behavior occurs to visualize the rotator in which the physical behavior occurs and the other component in which the physical behavior does not occur to display the motor 13b in the virtual space of the digital twin 3D model.

At this time, information about the driving unit 21 which is displayed in the virtual space of the digital twin 3D model by the information unit 22 refers to at least one information, among the structure 11, the process facility 12, the equipment 13, and the auxiliary equipment 14 which are configured in the sewage treatment facility 10 in which the physical behavior actually occurs.

As a specific example, when it is assumed that the driving unit 21 in which the actual physical behavior occurs is a pump of the equipment 13, the information unit 22 includes items, such as a size of the pump, the number of revolutions, and power consumption.

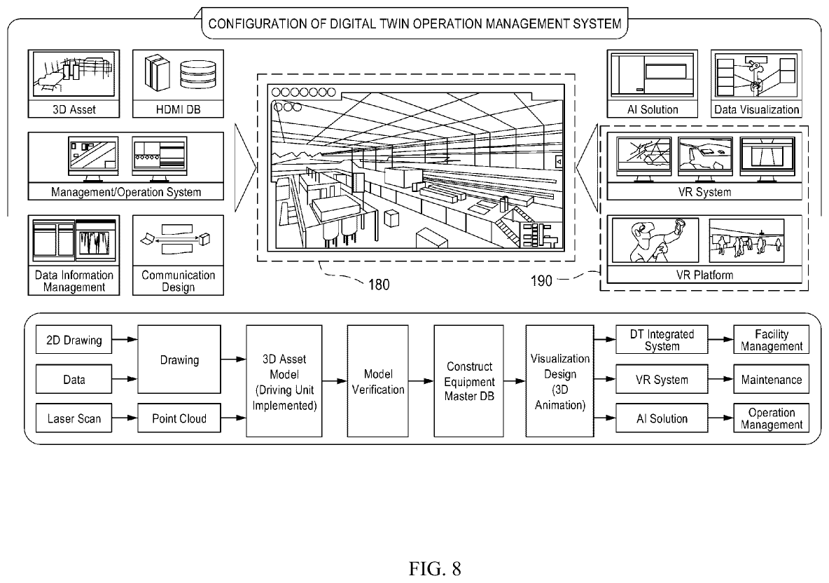

FIG. 8 is a view for explaining a providing method of a digital twin 3D model according to an exemplary embodiment of the present disclosure.

Referring to FIG. 8, the digital twin system unit 180 may present the digital twin 3D model to the user in the form of a user interface.

In the meantime, the sewage treatment facility operation management system 100 may further include a visualization unit 190 to provide the digital twin 3D model which is constructed by the digital twin system unit 180 to the user.

The visualization unit 190 may be a VR system which executes the contents based on a VR platform which is wearable to the body of the user and the hardware of the VR system may be a VR headset (HMD), a controller, a tracker, a sensor, a computer, or a console.

That is, when the user wears the visualization unit 190 on the body, the virtual space of the digital twin 3D model of the present disclosure may be provided to the user in the VR environment.

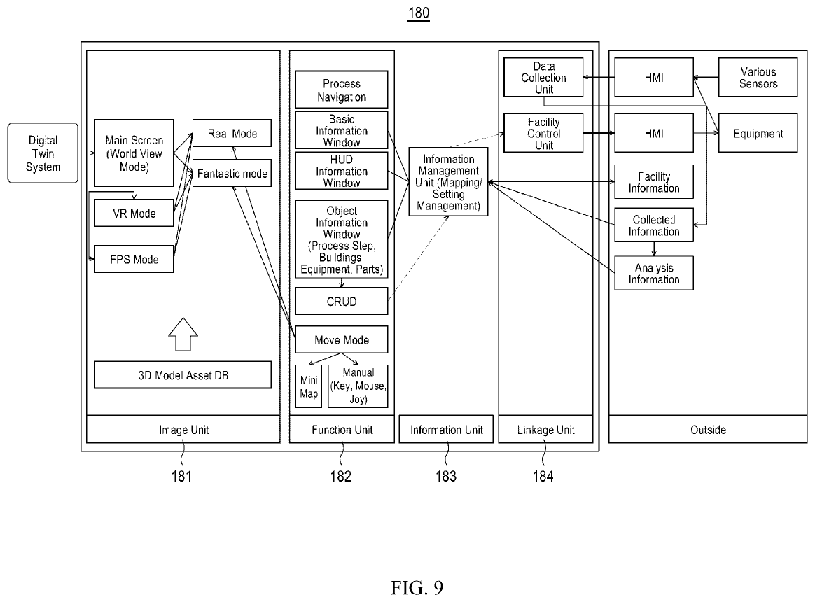

FIG. 9 is a view schematically illustrating a configuration of a digital twin system unit according to an exemplary embodiment of the present disclosure.

Referring to FIG. 9, the digital twin system unit 180 includes an image unit 181, a function unit 182, an information unit 183, and a linkage unit 184.

In one exemplary embodiment, the image unit 181 combines 3D assets 20 from a structuralized digital 3D model asset library DB to configure a main screen modeling of the virtual space of the digital twin 3D model and at this time, a world view model may be configured as a default.

At this time, the world view mode may be an image mode which provides a broad overview of the virtual space of the digital twin 3D model.

Further, the image unit 181 may build an FPS mode by utilizing the world view modeling and add an VR mode for virtual experience.

The image unit 181 is interlinked with the visualization unit 190 to implement the VR mode and the 3D image may be provided through the real mode and the fantastic mode.

Here, the real mode is a mode which emphasizes the realistic expression and an image mode which reproduces the actual environment as accurately as possible. Unlike the real mode, the fantastic mode is an image mode which emphasizes unrealistic or dramatic elements and may be used for external promotion of the sewage treatment facility operation management system 10->100.

In one exemplary embodiment, the function unit 182 may be configured by a function of controlling a process navigation and a movement mode, a basic information window in which the facility specifications and monitoring data are displayed, an HUD information window which displays measurement information in real time, and an object information window which displays related information, such as a process diagnosis and asset management, and maintenance histories.

In one exemplary embodiment, the information unit 183 serves to manage internal storage information and external linkage data to internally divide and analyze information of the linkage unit 184 and transmit the information to the function unit 182.

In one exemplary embodiment, the linkage unit 184 is configured together with the driving unit 21 and the information unit 22 to implement a digital twin 3D model and may serve as an interface which collects necessary data from external systems, such as an HMI, a process diagnosis system, an asset management system, which are external linkage targets and supplies internal information to the outside.

At this time, the information supply is managed by utilizing a standard RestAPI manner and the information may be designed to be collected in various manners, such as DB to DB, RestAPI, and files to DB.

Further, the linkage unit 184 may include security which follows the security guidelines of the National Intelligence Service and personal information protection regulations during the system linkage and enhances the security through a one-way linkage device in accordance with the operation policy for separating the administrative network and the control network.

As described above, the detailed description of the exemplary embodiments of the disclosed present disclosure is provided such that those skilled in the art implement and carry out the present disclosure. While the disclosure has been described with reference to the preferred embodiments, it will be understood by those skilled in the art that various changes and modifications of the present disclosure may be made without departing from the spirit and scope of the disclosure. For example, those skilled in the art may use configurations disclosed in the above-described exemplary embodiments by combining them with each other. Therefore, the present disclosure is not intended to be limited to the above-described exemplary embodiments but to assign the widest scope consistent with disclosed principles and novel features.

The present disclosure may be implemented in another specific form within the scope without departing from the technical spirit and essential feature of the present disclosure. Therefore, the detailed description should not restrictively be analyzed in all aspects and should be exemplarily considered. The scope of the present disclosure should be determined by rational interpretation of the appended claims and all changes are included in the scope of the present disclosure within the equivalent scope of the present disclosure. The present disclosure is not intended to be limited to the above-described exemplary embodiments but to assign the widest scope consistent with disclosed principles and novel features. Further, claims having no clear quoting relation in the claims are combined to configure the embodiment or may be included as new claims by correction after application.

What is claimed is:

1. A digital twin-based sewage treatment facility operation management system, comprising:
a data collection/storage unit which collects and stores data including a sewage treatment process operation parameter and an operation status of a sewage treatment facility in real time;
a water quality prediction unit which predicts an effluent water quality according to a sewage treatment process of the sewage treatment facility using the sewage treatment process operation parameter of the sewage treatment facility, based on an algorithm of an artificial intelligence model;
an anomaly detection unit which detects anomaly of each sewage treatment process of the sewage treatment facility when the effluent water quality predicted by the water quality prediction unit exceeds a predetermined water quality level, based on the algorithm of the artificial intelligence model;
an optimal parameter deduction unit which deduces the operation parameter of the sewage treatment process generated when the operation status of the sewage treatment facility is controlled, during the detection of the anomaly of the sewage treatment process by the anomaly detection unit, based on the algorithm of the artificial intelligence model; and
a digital twin system unit which constructs a digital twin 3D model which reproduces the sewage treatment facility as a virtual 3D graphic by applying a 3D asset of the sewage treatment facility, structuralizes the 3D asset to have attributes of a driving unit which is a set of dynamic information to reflect a physical behavior of the sewage treatment facility in the digital twin 3D model to a virtual space of the digital twin 3D model and an information unit which is a set of static information and includes an linkage unit which serves as an interface to collect data and provide information together with the driving unit and the information unit.

2. The digital twin-based sewage treatment facility operation management system according to claim 1, further comprising:
a comprehensive analysis unit which proceeds a simulation of a scenario assuming that the operation parameter of the sewage treatment process to the sewage treatment process and deduces a water quality prediction result obtained by predicting a water quality of the sewage treatment process based on the simulation.

3. The digital twin-based sewage treatment facility operation management system according to claim 2, wherein the operation parameter of the sewage treatment process is at least one setting value, among power consumption, a chemical dosing amount, a ventilation rate, a recycled sludge amount, hydraulic retention time (HRT), solid retention time (SRT), mixed liquor suspended solids (MLSS), and an internal recycle rate, which allows the water quality of the effluent water to comply with the predetermined water quality level.

4. The digital twin-based sewage treatment facility operation management system according to claim 2, wherein the digital twin system unit displays the water quality prediction result in the virtual space of the digital twin 3D model.

5. The digital twin-based sewage treatment facility operation management system according to claim 1, further comprising:
a monitoring unit which monitors the sewage treatment process operation parameter and the operation status of the sewage treatment facility which are stored in the data collection/storage unit in real time.

6. The digital twin-based sewage treatment facility operation management system according to claim 5, wherein the operation status of the sewage treatment facility includes an operation status of a process facility which is a subsystem of a structure which configures the sewage treatment facility and equipment which is a subsystem of the process facility.

7. The digital twin-based sewage treatment facility operation management system according to claim 5, wherein the digital twin system unit displays the sewage treatment process operation parameter and the operation status of the sewage treatment facility in the virtual space of the digital twin 3D model.

8. The digital twin-based sewage treatment facility operation management system according to claim 1, further comprising:
3D a structure information unit which transmits structure information to the digital twin system unit to allow the structure information to be displayed in the virtual space of the digital twin 3D model.

9. The digital twin-based sewage treatment facility operation management system according to claim 8, wherein the structure information is data including specifications, drawings, and photographs of a structure which configures the sewage treatment facility, a process facility which is a subsystem of the structure, equipment and auxiliary equipment which are subsystems of the process facility, maintenance histories and CCTV monitoring screens of the structure, the process facility, the equipment, and the auxiliary equipment.

10. The digital twin-based sewage treatment facility operation management system according to claim 9, wherein the digital twin system unit displays the structure information in the virtual space of the digital twin 3D model.

11. The digital twin-based sewage treatment facility operation management system according to claim 9, wherein after applying the 3D assets of the structure, the process facility, the equipment, and the auxiliary equipment which are the sewage treatment facility to extract 3D asset models of the structure, the process facility 3D, the equipment, and the auxiliary equipment, respectively, the digital twin system unit configures an asset hierarchy in which a structure 3D asset model serves as a supersystem of a process facility 3D asset model and the process facility 3D asset model serves as a supersystem of an equipment 3D asset model and an auxiliary equipment 3D asset model to organize a relationship between the 3D asset models, and displays the 3D asset models of the structure, the process facility, the equipment, and the auxiliary equipment in the virtual space of the digital twin 3D model based on a configuration of the asset hierarchy.

12. The digital twin-based sewage treatment facility operation management system according to claim 11, wherein the process facility is a reaction tank including a primary precipitate tank, an anaerobic tank, an anoxic tank, an aerobic tank, or a biofilm, and a sequencing batch reactor.

13. The digital twin-based sewage treatment facility operation management system according to claim 11, wherein the equipment is a pump, a valve, and a motor which operate to proceed the sewage treatment process.

14. The digital twin-based sewage treatment facility operation management system according to claim 11, wherein the auxiliary equipment is a foothold and a fence installed in the structure.

15. The digital twin-based sewage treatment facility operation management system according to claim 1, wherein the digital twin system unit presents the digital twin 3D model to a user in a form of a user interface.
